(19) United States
(12) Patent Application Publication
(10) Pub. No.: US 2008/0214006 A1
(43) Pub. Date: Sep. 4, 2008

(54) METHODS OF USING CORROSION-INHIBITING CLEANING COMPOSITIONS FOR METAL LAYERS AND PATTERNS ON SEMICONDUCTOR SUBSTRATES

(76) Inventors: Kwang-Wook Lee, Gyeonggi-do (KR); In-Seak Hwang, Gyeonggi-do (KR); Yong-Sun Ko, Gyeonggi-do (KR); Byoung-Moon Yoon, Gyeonggi-do (KR); Kyung-Hyun Kim, Seoul (KR); Ky-Sub Kim, Jeollabuk-do (KR); Sun-Young Song, Jeollabuk-do (KR); Hyuk-Jin Lee, Jeollabuk-do (KR); Byung-Mook Kim, Jeollabuk-do (KR)

Correspondence Address: MYERS BIGEL SIBLEY & SAJOVEC, PO BOX 37428, RALEIGH, NC, 27627, US

(21) Appl. No.: 12/122,264

(22) Filed: May 16, 2008

Related U.S. Application Data
(62) Division of application No. 11/021,040, filed on Dec. 23, 2004.

(30) Foreign Application Priority Data
Feb. 10, 2004 (KR) 2004-8798
May 18, 2004 (KR) 2004-35210

(51) Int. Cl. H01L 21/461; G03C 1/00

(52) U.S. Cl. 438/692; 430/616; 257/E21.496

(57) ABSTRACT

Provided herein are methods for using corrosion-inhibiting cleaning compositions for semiconductor wafer processing that include an aqueous admixture of at least water, a surfactant and a corrosion-inhibiting compound selected from a group consisting of amino phosphonates, polyamines and polycarboxylic acids. The quantity of the corrosion-inhibiting compound in the admixture is preferably in a range from about 0.0001 wt % to about 0.1 wt % and the quantity of the surfactant is preferably in a range from about 0.001 wt % to about 1.0 wt %. The aqueous admixture may also include sulfuric acid and a fluoride, which act as oxide etchants, and a peroxide, which acts as a metal etchant.

### REFERENCE TO PRIORITY APPLICATION

This application claims priority to and is a divisional of parent application Ser. No. 11/021,040, filed Dec. 23, 2004, which claims the benefit of Korean Application Serial Nos. 2004-8798, filed Feb. 10, 2004 and 2004-35210, filed May 18, 2004, the disclosures of each which are hereby incorporated herein by reference.

### FIELD OF THE INVENTION

The present invention relates to methods of forming integrated circuit devices and, more particularly, to methods of cleaning and polishing metal layers on integrated circuit substrates.

### BACKGROUND OF THE INVENTION

Integrated circuit chips frequently utilize multiple levels of patterned metallization and conductive plugs to provide electrical interconnects between active devices within a semiconductor substrate. To achieve low resistance interconnects, tungsten metal layers have been deposited and patterned as electrodes (e.g., gate electrodes), conductive plugs and metal wiring layers. The processing of tungsten and other metal layers frequently requires the use of cleaning compositions to remove polymer and other residues from the metal layers. Such residues may remain after conventional processing steps such as resist ashing. Unfortunately, the use of cleaning compositions that remove residues from metal layers may lead to metal layer corrosion from chemical etchants.

Cleaning compositions configured to inhibit metal corrosion during semiconductor wafer processing have been developed. One such cleaning composition is disclosed in U.S. Pat. No. 6,117,795 to Pasch. This cleaning composition includes using a corrosion inhibiting compound, such as an azole compound, during post-etch cleaning. Corrosion inhibiting compounds may also be used to inhibit corrosion of metal patterns during chemical-mechanical polishing (CMP). Such compounds, which include at least one of sulfur containing compounds, phosphorus containing compounds and azoles, are disclosed in U.S. Pat. Nos. 6,068,879 and 6,383,414 to Pasch. U.S. Pat. No. 6,482,750 to Yokoi also discloses corrosion inhibiting compounds that are suitable for processing tungsten metal layers and U.S. Pat. No. 6,194,366 to Naghshineh et al. discloses corrosion inhibiting compounds that are suitable for processing copper containing microelectronic substrates. Additional cleaning compositions containing decontaminating agents selected from polycarboxylic acids, ammonium salts thereof and polyaminocarboxylic acids are disclosed in U.S. Pat. Nos. 6,387,190 and 6,767,409 to Aoki et al. Organic carboxylic acids may also be used in anti-corrosive cleaning compositions for removing plasma etching residues, as disclosed in U.S. Pat. No. 6,413,923 to Honda et al.

Notwithstanding these cleaning and corrosion-inhibiting compositions for semiconductor wafer processing, there continues to be a need for compositions having enhanced cleaning and corrosion-inhibiting characteristics.

### SUMMARY OF THE INVENTION

Embodiments of the present invention include corrosion-inhibiting cleaning compositions for semiconductor wafer processing. These compositions include an aqueous admixture of at least water, a surfactant and a corrosion-inhibiting compound selected from a group consisting of amino phosphonates, polyamines and polycarboxylic acids. The quantity of the corrosion-inhibiting compound in the admixture is preferably in a range from about 0.0001 wt % to about 0.1 wt % and the quantity of the surfactant is preferably in a range from about 0.001 wt % to about 1.0 wt %. In some embodiments of the invention, the surfactant may be selected from a group consisting of polyoxyethylene/polyoxypropylene glycol, a condensate of polyoxyethylene/polyoxypropylene ethylenediamine, a condensate of cyclizated oxyethylene ethylenediamine, a fatty acid ester, a fatty acid amid, an oxyethylene fatty acid amid and a polyglycine fatty acid ester.

The aqueous admixture also includes sulfuric acid and a fluoride, which act as oxide etchants, and a peroxide, which acts as a metal etchant. The quantity of the sulfuric acid in the admixture is preferably in a range from about 0.05 wt % to about 15 wt % and the quantity of the peroxide in the admixture is preferably in a range from about 0.5 wt % to about 15 wt %. The quantity of the fluoride in the admixture is also preferably in a range from about 0.001 wt % to about 0.2 wt %. The peroxide is preferably hydrogen peroxide, however, other peroxides selected from the group consisting of ozone, peroxosulfuric acid, peroxophosphoric acid, peracetic acid, perbenzoic acid and perphthalic acid. The fluoride may be selected from the group consisting of hydrogen fluoride, ammonium fluoride, tetramethylammonium fluoride, ammonium hydrogen fluoride, fluorboric acid and tetramethylammonium tetrafluoroborate.

In further embodiments of the present invention, the corrosion-inhibiting cleaning solution consists essentially of a surfactant, a corrosion-inhibiting compound selected from a group consisting of amino phosphonates, polyamines and polycarboxylic acids, first and second oxide etchants, a metal etchant and deionized water. In these embodiments, the corrosion-inhibiting compound acts as a chelating agent that attaches to and inhibits corrosion of a patterned metal layer (e.g., tungsten metal layer) on a semiconductor substrate when a cleaning step is performed to remove etching and other residues from the metal layer and other exposed portions of the substrate.

Additional embodiments of the invention include methods of forming integrated circuit devices by forming a gate oxide layer on an integrated circuit substrate and forming a tungsten metal layer on the gate oxide layer. The tungsten metal layer and the gate oxide layer are patterned to define a tungsten-based insula ted gate electrode. The patterned tungsten metal layer is then exposed to a cleaning solution containing a surfactant, first and second oxide etchants, a metal etchant, deionized water and a corrosion-inhibiting compound selected from a group consisting of amino phosphonates, polyamines and polycarboxylic acids. The quantity of the corrosion-inhibiting compound in the cleaning solution is preferably in a range from about 0.0001 wt % to about 0.1 wt % and the quantity of the surfactant in the cleaning solution is in a range from about 0.001 wt % to about 1.0 wt %.

Still further embodiments of the present invention include methods of forming memory devices by forming an interlayer dielectric layer on an integrated circuit substrate and forming an interconnect opening in the interlayer dielectric layer. The interconnect opening may be filled with a conductive plug. A bit line node may be formed on the conductive plug in a manner that provides an electrical connection between the bit line node and the conductive plug. The bit line node may be formed using a patterning step that includes chemically etching a metal layer (e.g., tungsten metal layer). The patterned bit line node is then exposed to a cleaning solution comprising a surfactant, a corrosion-inhibiting compound selected from a group consisting of amino phosphonates, polyamines and polycarboxylic acids, first and second oxide etchants, a metal etchant and deionized water. The corrosion-inhibiting compound acts as a chelating agent that attaches to exposed surfaces on the bit line node during the cleaning step. After cleaning, the semiconductor substrate may be rinsed in deionized water to remove any constituents of the cleaning solution.

### BRIEF DESCRIPTION OF THE DRAWINGS

FIGS. 1A-1D are cross-sectional views of intermediate structures that illustrate methods of cleaning metal layers on semiconductor substrates according to embodiments of the present invention.

FIGS. 2A-2F are cross-sectional views of intermediate structures that illustrate methods of cleaning metal layers on semiconductor substrates according to additional embodiments of the present invention.

### DETAILED DESCRIPTION OF PREFERRED EMBODIMENTS

The present invention now will be described more fully herein with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

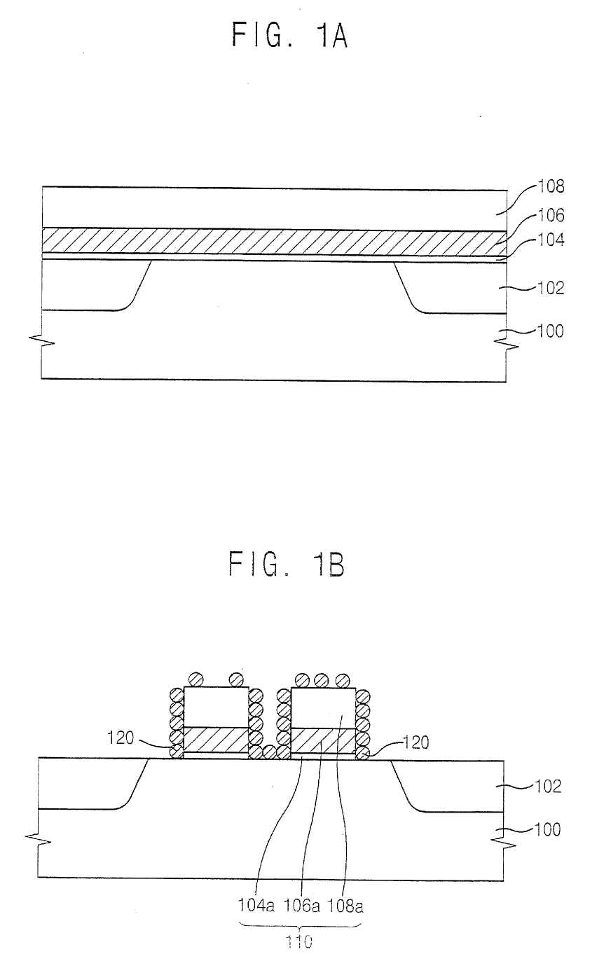

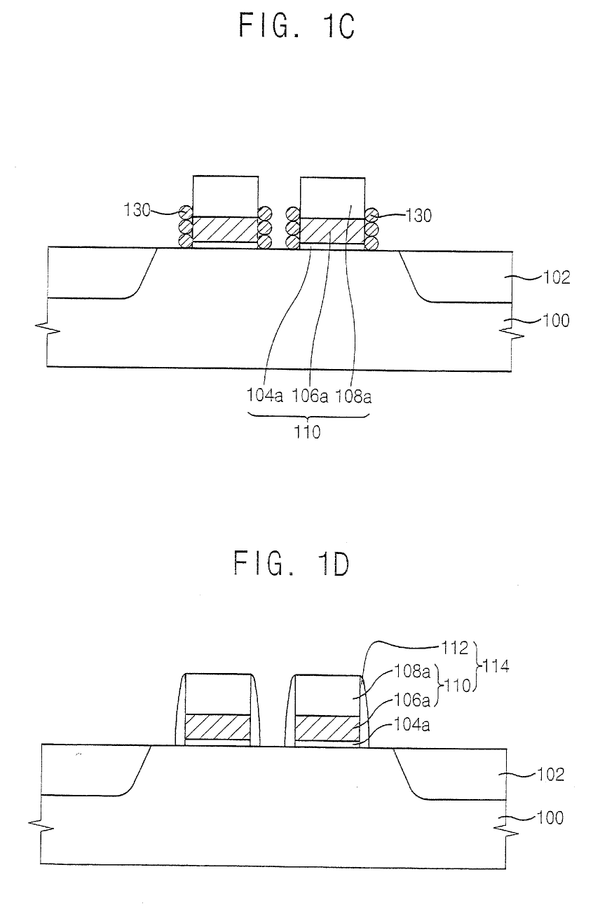

Methods of cleaning metal layers on semiconductor substrates include cleaning tungsten-based gate electrodes. As illustrated by FIG. 1A, these methods include forming a gate oxide layer 104 on a semiconductor substrate 100 having at least one semiconductor active region therein. This active region may be defined by a plurality of trench-based isolation regions 102, which may be formed using conventional shallow trench isolation (STI) techniques. A gate metal layer 106 is also formed on the gate oxide layer 104. This gate metal layer 106 may be formed as a blanket tungsten metal layer using a deposition technique such as chemical vapor deposition (CVD). A layer of electrically insulating capping material 108 (e.g., photoresist) is deposited on the gate metal layer 106. As illustrated by FIG. 1B, the layer of capping material 108 may be photolitographically patterned (e.g., using a photoresist layer (not shown)) and then used as an etching mask to define a plurality of gate patterns 110. Each of these gate patterns 110 is illustrated as including a patterned gate oxide 104a, a patterned metal gate electrode 106a and a patterned capping layer 108a. During these steps, including photoresist removal (e.g., by plasma ashing), polymer and other residues 120 may be formed on the sidewalls of the gate patterns 110 and on other exposed surfaces. As described more fully herein, these residues 120 may be removed using a cleaning solution that contains a plurality of etchants and at least one corrosion-inhibiting compound that operates to protect exposed sidewalls of the patterned metal gate electrodes 106a. As illustrated by FIG. 1C, the corrosion-inhibiting agents 130 within the cleaning solution may chelate with the exposed sidewalls of the patterned metal gate electrodes 106a and thereby inhibit chemical reaction between the exposed sidewalls and etchants within the cleaning solution. The cleaning step can be followed by a rinsing step, which removes any remaining residues 120 and corrosion-inhibiting agents 130 from the substrate 100. Electrically insulating sidewall spacers 112 may then be formed on the gate patterns 110, to thereby define a plurality of insulated gate electrodes 114 as illustrated by FIG. 1D. These sidewall spacers 112 may be formed by depositing and etching-back an electrically insulating layer using conventional techniques.

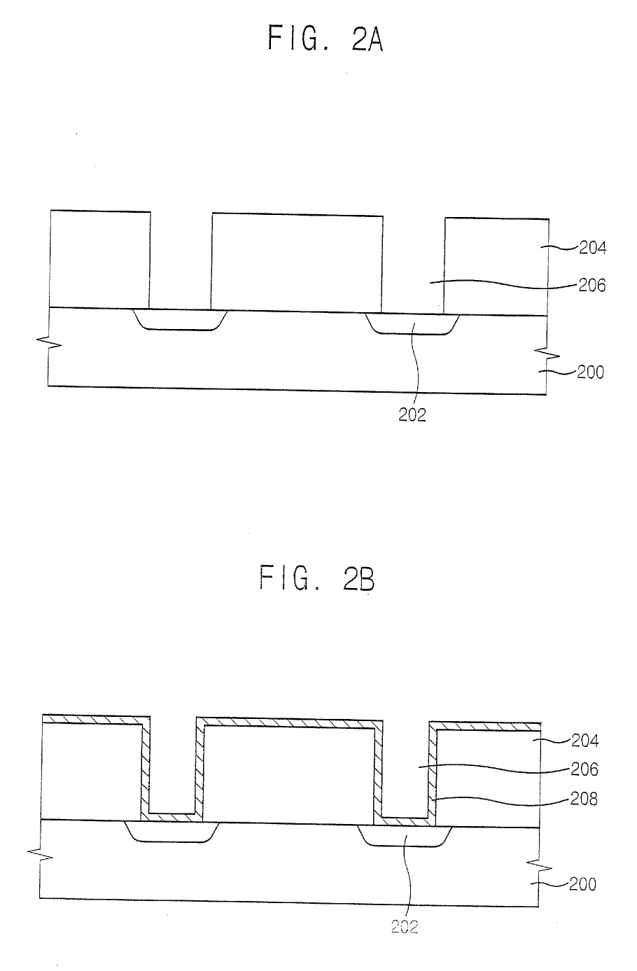

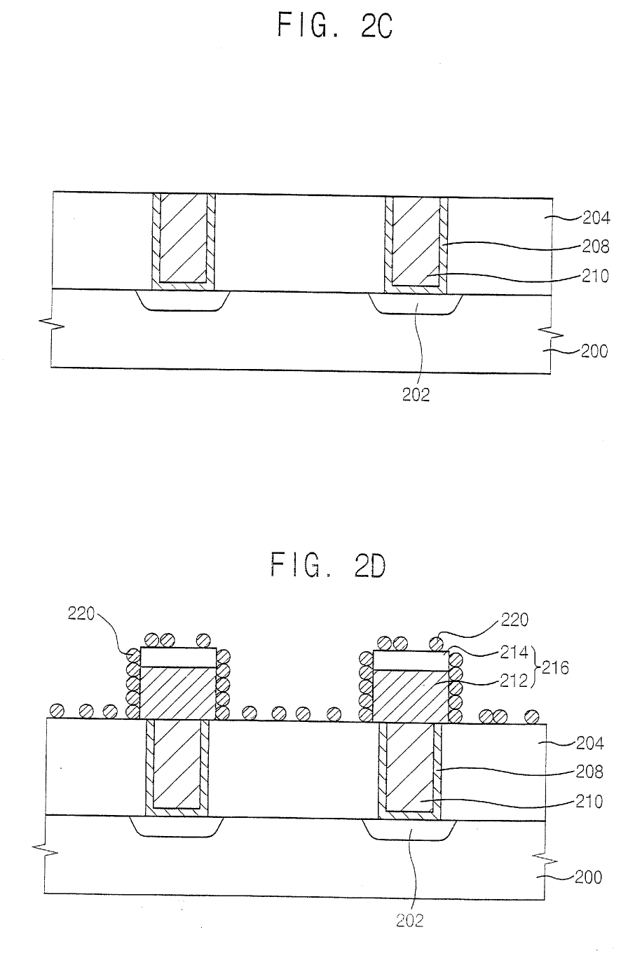

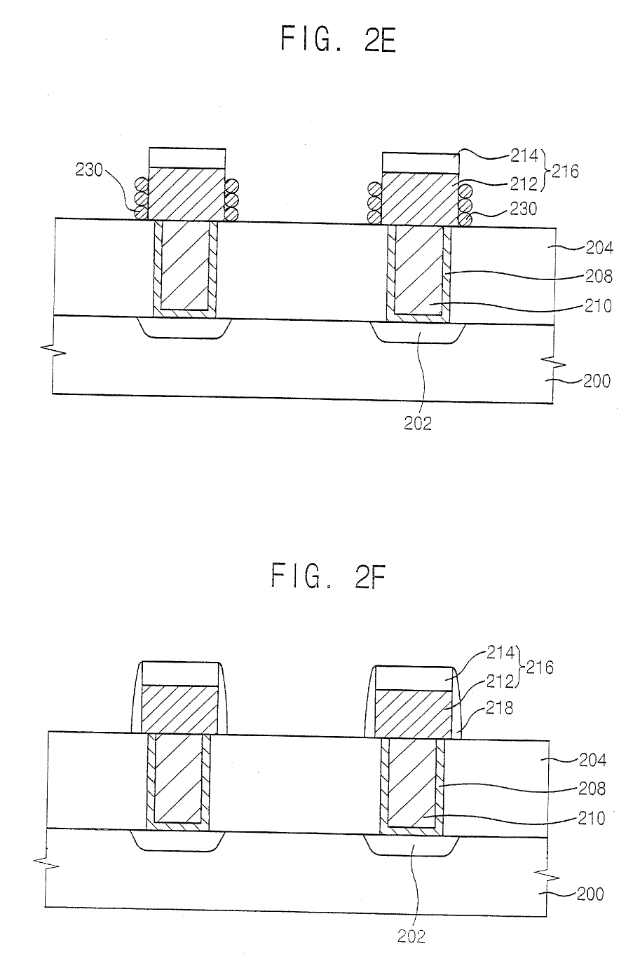

Additional methods of cleaning metal layers on semiconductor substrates may also include cleaning metal-based bit lines in semiconductor memory devices. As illustrated by FIG. 2A, these methods include forming an interlayer dielectric layer 204 on a semiconductor substrate 200. Although not shown, this interlayer dielectric layer 204 may be formed after the insulated gate electrodes 114 of FIG. 1D are formed on the substrate 200. The interlayer dielectric layer 204 is then patterned to define a plurality of contact holes 206 that expose respective diffusion regions 202 (e.g., source/drain and contact regions) within the substrate 200. Conventional techniques may then be used to conformally deposit a barrier metal layer 208 on the patterned interlayer dielectric layer 204. This barrier metal layer 208 may be a titanium layer (Ti), a titanium nitride layer (TiN) or a titanium/titanium nitride composite layer, for example.

An electrically conductive layer (e.g., aluminum (Al) or tungsten (W)) is then deposited on the barrier metal layer 208. This electrically conductive layer is deposited to a sufficient thickness to fill the contact holes 206. A chemical-mechanical polishing (CMP) step may then be performed on the electrically conductive layer to thereby define a plurality of conductive plugs 210 within the contact holes 206. This CMP step may include the use of a slurry composition having the corrosion-inhibiting characteristics described herein with respect to the cleaning solutions.

As illustrated by FIG. 2C, this polishing step is performed for a sufficient duration to expose a planarized interlayer dielectric layer 204. Referring now to FIG. 2D, a plurality of bit line nodes 216 may be formed on respective ones of the conductive plugs 210. These bit line nodes 216 may be formed by sequentially depositing a bit line metal layer 212 and a bit line capping layer 214 on the interlayer dielectric layer 204 and then patterning these layers into separate bit line nodes 216. As illustrated, this patterning step may result in the formation of polymer and other residues 220 on the exposed surfaces of the patterned layers. These residues 220 may be removed using a cleaning solution that contains a plurality of etchants and at least one corrosion-inhibiting compound that operates to protect exposed sidewalls of the bit line nodes 216. As illustrated by FIG. 2E, the corrosion-inhibiting agents 230 within the cleaning solution may chelate with the exposed sidewalls of the bit line nodes 216 and thereby inhibit chemical reaction between these exposed sidewalls and etchants within the cleaning solution. As illustrated by FIG. 2F, the cleaning step can be followed by a rinsing step, which removes any remaining residues 220 and corrosion-inhibiting agents 230 from the substrate 200. Electrically insulating bit line spacers 218 may then be formed on the bit line nodes 216, to thereby define a plurality of insulated bit lines. These sidewall spacers 218 may be formed by depositing and etching-back an electrically insulating dielectric layer (e.g., SiO₂ layer) using conventional techniques.

The above-described corrosion-inhibiting cleaning solutions include an aqueous admixture of at least water, a surfactant and a corrosion-inhibiting compound selected from a group consisting of amino phosphonates, polyamines and polycarboxylic acids. Corrosion-inhibiting compounds within this group include pentamethyldiethylentriamine (PMDETA), tetramethylethylenediamine (TMEDA), ethylenediaminetetraacetic acid (EDTA), diethylenetriaminepentaacetic acid (DTPA), N-(2-hydroxyethyl)ethylenediaminetriacetic acid (HEDTA), glycoletherdiaminetetraacetic acid (GEDTA), triethylenetetraaminehexaacetic acid (TTHA), 1,3 propanediaminetetraacetic acid (PDTA), 1,3-diamino-2-hydroxypropanetetraacetic acid (PDTA-OH), aminotris(methylphosphoric acid) (ATMPA) (a/k/a nitrilotrismethylenetriphosphonic acid (NTMP)), ethylenediaminetetramethylenephosphonic acid (EDTMPA), diethylenetriaminepentamethylenephosphonic acid (DTPMPA) and hexamethylenediaminetetramethylenephosphonic acid (HDTMPA). Additional corrosion-inhibiting compounds that may be used in additional embodiments of the invention include those having the following formula:

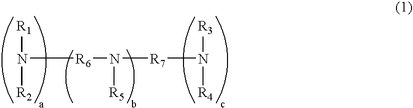

wherein R₁ through R₅ are each independently selected from the group consisting of hydrogen, alkyl, hydroxyalkyl, aryl, —(CH₂)ⱼCOOH, —P(═O)(OH)₂, and —(CH₂)ₖP(═O)(OH)₂; wherein “j” and “k” are each independent integers ranging from 1 to 6; wherein R₆ and R₇ are each independently alkylene, oxyalkylene, or polyoxyalkylene chains having from 1 to 6 carbon atoms; wherein the alkylene, monoxyalkylene or polyoxyalkylene chains are straight or branched; wherein the alkylene, monoxyalkylene or polyoxyalkylene chains are either unsubstituted or substituted with one or more substituents selected from the group consisting of hydroxyl, hydroxyalkyl, aryl, —(CH₂)ₘCOOH, and (CH₂)ₙP(═O)(OH)₂; wherein “m” and “n” are each independent integers ranging from 0 to 6; and wherein “a” and “c” are either 0 or 1, “b” is an integer ranging from 0 to 2, and a+b+c≧1.

The quantity of the corrosion-inhibiting compound in the admixture is preferably in a range from about 0.0001 wt % to about 0.1 wt % and the quantity of the surfactant is preferably in a range from about 0.001 wt % to about 1.0 wt %. The surfactant may be selected from a group consisting of polyoxyethylene/polyoxypropylene glycol, a condensate of polyoxyethylene/polyoxypropylene and ethylenediamine, a condensate of cyclizated oxyethylene and ethylenediamine, a fatty acid ester, a fatty acid amide, an oxyethylene fatty acid amide and a polyglycerine fatty acid ester. A preferred surfactant in this group is a condensate of polyoxyethylene/polyoxypropylene and ethylenediamine. Additional surfactants include those having the following formula:

R₈-[{(EO)ₓ—(PO)_{y}}_{z}—H]_{q} (2)

where: “EO” designates an oxyethylene group; “PO” designates a oxypropylene group; “R8” designates hydroxy or a residue formed by eliminating hydrogen atoms from a hydroxyl group of alcohol or amine or a residue formed by eliminating hydrogen atoms from an amino acid; “x” and “y” are positive integers satisfying 0.05≦x/(x+y)≦0.4 and “z” and “q” are positive integers less than 5. When the relationship x/(x+y) is less than 0.05, the solubility of the surfactant is poor and when the relationship is greater than 0.4 the ‘bubble’ effect of the surfactant is poor. Moreover, when the total molecular weight of the oxypropylene group is less than 500, the cleaning composition has relatively poor cleaning and rinsing characteristics and when the total molecular weight of the oxypropylene group is greater than 5000, the surfactant has relatively poor solubility characteristics. A preferred total molecular weight of the oxypropylene group is in a range from about 1000 to about 3500.

The aqueous admixture also includes sulfuric acid and a fluoride, which act as oxide etchants, and a peroxide, which acts as a metal etchant. The quantity of the sulfuric acid in the admixture is preferably in a range from about 0.05 wt % to about 15 wt % and the quantity of the peroxide in the admixture is preferably in a range from about 0.5 wt % to about 15 wt %. The quantity of the fluoride in the admixture is also preferably in a range from about 0.001 wt % to about 0.2 wt %. The peroxide is preferably hydrogen peroxide, however, other peroxides selected from the group consisting of ozone, peroxosulfuric acid, peroxophosphoric acid, peracetic acid, perbenzoic acid and perphthalic acid. The fluoride may be selected from the group consisting of hydrogen fluoride, ammonium fluoride, tetramethylammonium fluoride, ammonium hydrogen fluoride, fluorboric acid and tetramethylammonium tetrafluoroborate. Of these fluorides, hydrogen fluoride is typically the most preferred fluoride. The pH of the aqueous admixture also influences the cleaning effectiveness and etching characteristics of the cleaning composition. A cleaning composition having a pH of lower than 0.1 generally results in good polymer removal ability but excessive etching of metal and oxide layers. A cleaning composition having a pH of higher than 4.0 generally results in poor polymer removal ability. A preferred pH for the cleaning compositions described herein is in a range from about 0.5 to about 2.0.

TABLE 1 illustrates the compositions in a plurality of example and comparison cleaning solutions containing varying concentrations of sulfuric acid (H₂SO₄), hydrogen peroxide (H₂O₂) and hydrogen fluoride (HF), with mostly fixed concentrations of a preferred amino phosphonate (e.g., ethylenediaminetetramethylenephosphoric acid (EDTMPA)) as a corrosion-inhibiting agent (C-I agent), and a preferred surfactant (e.g., a condensate of polyoxyethylene/polyoxypropylene and ethylenediamine). The cleaning compositions of TABLE 1 were used to clean a patterned tungsten layer having a thickness of about 1000 [symbol] and a patterned oxide layer (e.g., borophosphosilicate glass (BPSG)) having a thickness of about 1000 [symbol] TABLE 2 illustrates a “Y” condition for those cases where the tungsten etch rate is less than 40 [symbol] and an “X” condition for those cases where the tungsten etch rate is greater than 40 [symbol] TABLE 2 also illustrates a “Y” condition for those cases where the oxide layer etch rate is less than 50 [symbol] and an “X” for those cases where the oxide etch rate is greater than 50

[symbol]

TABLE 1

| | H2SO4 | H2O2 | HF | C-I AGENT | SURFACTANT | DI WATER |
|---|---|---|---|---|---|---|
| Example 1 | 1 | 5 | 0.05 | 0.05 | 0.05 | 93.85 |
| Example 2 | 3 | 5 | 0.05 | 0.05 | 0.05 | 91.85 |
| Example 3 | 5 | 5 | 0.05 | 0.05 | 0.05 | 89.85 |
| Example 4 | 7 | 5 | 0.05 | 0.05 | 0.05 | 87.85 |
| Example 5 | 10 | 5 | 0.05 | 0.05 | 0.05 | 84.85 |
| Example 6 | 10 | 1 | 0.05 | 0.05 | 0.05 | 88.85 |
| Example 7 | 10 | 3 | 0.05 | 0.05 | 0.05 | 86.85 |
| Example 8 | 10 | 5 | 0.05 | 0.05 | 0.05 | 84.85 |
| Example 9 | 10 | 7 | 0.05 | 0.05 | 0.05 | 82.85 |
| Example 10 | 10 | 10 | 0.05 | 0.05 | 0.05 | 79.85 |
| Example 11 | 10 | 3 | 0.01 | 0.05 | 0.05 | 86.89 |
| Example 12 | 10 | 7 | 0.01 | 0.05 | 0.05 | 82.89 |
| Example 13 | 10 | 3 | 0.1 | 0.05 | 0.05 | 86.80 |
| Example 14 | 10 | 7 | 0.1 | 0.05 | 0.05 | 82.80 |
| Example 15 | 10 | 3 | 0.05 | 0.001 | 0.05 | 86.899 |
| Example 16 | 10 | 3 | 0.05 | 0.01 | 0.05 | 86.89 |
| Example 17 | 10 | 3 | 0.05 | 0.05 | 0.1 | 86.80 |
| Example 18 | 10 | 3 | 0.05 | 0.05 | 1 | 85.90 |
| Compare 1 | 5 | 2 | 0.05 | — | — | 92.95 |
| Compare 2 | 5 | 2 | 0.05 | 0.05 | — | 92.90 |
| Compare 3 | 5 | 2 | — | — | 0.05 | 92.95 |

TABLE 2

| | Tungsten Pattern | | Polymer Removal |
|---|---|---|---|
| | Attack | Oxide Layer Attack | Ability |
| Example 1 | Y | Y | GOOD |
| Example 2 | Y | Y | GOOD |
| Example 3 | Y | Y | GOOD |
| Example 4 | Y | Y | GOOD |
| Example 5 | Y | Y | GOOD |
| Example 6 | Y | Y | GOOD |
| Example 7 | Y | Y | GOOD |
| Example 8 | Y | Y | GOOD |
| Example 9 | Y | Y | GOOD |
| Example 10 | Y | Y | GOOD |
| Example 11 | Y | Y | GOOD |
| Example 12 | Y | Y | GOOD |
| Example 13 | Y | Y | GOOD |
| Example 14 | Y | Y | GOOD |
| Example 15 | Y | Y | GOOD |
| Example 16 | Y | Y | GOOD |
| Example 17 | Y | Y | GOOD |
| Example 18 | Y | Y | GOOD |
| Compare 1 | X | X | GOOD |
| Compare 2 | Y | X | GOOD |
| Compare 3 | X | Y | GOOD |

As illustrated by TABLE 2, each of the comparison cleaning solutions (COMPARE 1-3) have good polymer removal ability, but poor tungsten and/or oxide etching characteristics.

Analysis of additional example solutions demonstrates that using less than 0.0001 wt % of the corrosion-inhibiting agent results in poor corrosion inhibition and that a degree of corrosion inhibition saturates at levels greater than about 0.1 wt %. This analysis also demonstrates that using less than 0.5 wt % of peroxide results in poor polymer removal ability and using greater than 15 wt % of peroxide results in metal layer over-etch. A more preferred range for the peroxide extends from about 0.5 wt % to about 10 wt %. The analysis further demonstrates that using less than 0.001 wt % of fluoride results in poor oxide polymer removal ability and using greater than 0.2 wt % of fluoride results in oxide layer over-etch and lifting of metal patterns. A more preferred range for the fluoride extends from about 0.01 wt % to about 0.1 wt %.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A method of forming an integrated circuit device, comprising the steps of:
forming a gate oxide layer on an integrated circuit substrate;
forming a tungsten metal layer on the gate oxide layer;
patterning the tungsten metal layer and gate oxide layer to define a tungsten-based insulated gate electrode; and
exposing the patterned tungsten metal layer to a cleaning solution comprising a surfactant, a corrosion-inhibiting compound selected from a group consisting of amino phosphonates, polyamines and polycarboxylic acids, first and second oxide etchants, a metal etchant and deionized water.

2. The method of claim 1, wherein a quantity of the corrosion-inhibiting compound in the cleaning solution is in a range from about 0.0001 wt % to about 0.1 wt %; wherein a quantity of the surfactant in the cleaning solution is in a range from about 0.001 wt % to about 1.0 wt %; and wherein the first oxide etchant is sulfuric acid, the second oxide etchant is a fluoride and the metal etchant is a peroxide.

3. The method of claim 2, wherein a quantity of the sulfuric acid in the cleaning solution is in a range from about 0.05 wt % to about 15 wt %; and wherein a quantity of the peroxide in the cleaning solution is in a range from about 0.5 wt % to about 15 wt %.

4. The method of claim 3, wherein the peroxide is hydrogen peroxide (H₂O₂) and the fluoride is hydrogen fluoride (HF).

5. A method of forming a memory device, comprising the steps of:
forming an interlayer dielectric layer on an integrated circuit substrate;
forming an interconnect opening in the interlayer dielectric layer;
filling the interconnect opening with a conductive plug;
forming a bit line node electrically coupled to the conductive plug;
exposing the bit line node to a cleaning solution comprising a surfactant, a corrosion-inhibiting compound selected from a group consisting of amino phosphonates, polyamines and polycarboxylic acids, first and second oxide etchants, a metal etchant and deionized water.

6. The method of claim 5, wherein a quantity of the corrosion-inhibiting compound in the cleaning solution is in a range from about 0.0001 wt % to about 0.1 wt %; wherein a quantity of the surfactant in the cleaning solution is in a range from about 0.001 wt % to about 1.0 wt %; and wherein the first oxide etchant is sulfuric acid, the second oxide etchant is a fluoride and the metal etchant is a peroxide.

7. The method of claim 6, wherein a quantity of the sulfuric acid in the cleaning solution is in a range from about 0.05 wt % to about 15 wt %; and wherein a quantity of the peroxide in the cleaning solution is in a range from about 0.5 wt % to about 15 wt %.

8. The method of claim 7, wherein the peroxide is hydrogen peroxide (H₂O₂) and the fluoride is hydrogen fluoride (HF).

9. A method of forming an integrated circuit device, comprising the steps of:
forming a gate oxide layer on an integrated circuit substrate;
forming a tungsten metal layer on the gate oxide layer;
patterning the tungsten metal layer and gate oxide layer to define a tungsten-based insulated gate electrode; and
exposing the patterned tungsten metal layer to a cleaning solution consisting essentially of a surfactant, a corrosion-inhibiting compound selected from a group consisting of amino phosphonates, polyamines and polycarboxylic acids, hydrogen fluoride, hydrogen peroxide, sulfuric acid and deionized water.
